(19) United States
(12) Patent Application Publication
(10) Pub. No.: US 2026/0120730 A1
(43) Pub. Date: Apr. 30, 2026

(54) SEMICONDUCTOR DEVICE HAVING HYBRID MEMORY LAYERS AND METHOD OF MANUFACTURING THE SAME

(71) Applicant: SK hynix Inc., Icheon-si (KR)

(72) Inventor: Won Tae KOO, Icheon-si (KR)

(21) Appl. No.: 19/205,797

(22) Filed: May 12, 2025

(30) Foreign Application Priority Data
Oct. 30, 2024 (KR) 10-2024-0150974

(51) Int. Cl. G11C 5/06; H10B 51/20; H10B 63/00; H10D 64/01; H10D 64/66; H10D 64/68; H10N 70/00

(52) U.S. Cl. CPC G11C 5/063; H10B 51/20; H10B 63/84; H10D 64/033; H10D 64/662; H10D 64/689; H10N 70/021; H10N 70/841; H10N 70/8833

(57) ABSTRACT

A semiconductor device includes a first interconnection line extending in a first direction; a second interconnection line extending in a second direction; and a memory cell disposed between the first interconnection line and the second interconnection line. The memory cell includes a first electrode; a first memory layer including a ferroelectric layer over the first electrode; a second electrode over the first memory layer; a second memory layer including a high-k dielectric layer over the second electrode; an oxygen reservoir layer over the second memory layer; and a third electrode over the oxygen reservoir layer.

### CROSS-REFERENCE TO RELATED APPLICATION

The present application claims priority under 35 U.S.C § 119 (a) to Korean Patent Application No. 10-2024-0150974, filed on Oct. 30, 2024, in the Korean Intellectual Property Office, which is incorporated herein by reference in its entirety.

### BACKGROUND

### 1. Field

The present disclosure relates to a semiconductor device and a method of manufacturing a semiconductor device. In particular, a semiconductor device having hybrid memory layers and a method of manufacturing the semiconductor device having hybrid memory layers are disclosed.

### 2. Description of the Related Art

Semiconductor devices having a ferroelectric layer are being studied. A ferroelectric layer has low power consumption because it has low on-current characteristics. However, a hybrid memory layer can have a very low on-current and low on/off current ratio. Thus, a hybrid memory layer is hard to use in semiconductor devices.

### SUMMARY

An embodiment of the present disclosure provides a semiconductor device having hybrid memory layers.

An embodiment of the present disclosure provides a semiconductor device having a ferroelectric memory layer and a variable resistance layer.

An embodiment of the present disclosure provides a method of manufacturing a semiconductor device having hybrid memory layers.

An embodiment of the present disclosure provides a method of manufacturing a semiconductor device having a ferroelectric memory layer and a variable resistance layer.

In accordance with an embodiment of the present disclosure, a semiconductor device includes a first interconnection line extending in a first direction; a second interconnection line extending in a second direction; and a memory cell disposed between the first interconnection line and the second interconnection line. The memory cell includes a first electrode; a first memory layer including a ferroelectric layer disposed over the first electrode; a second electrode disposed over the first memory layer; a second memory layer including a high-k dielectric layer disposed over the second electrode; an oxygen reservoir layer disposed over the second memory layer; and a third electrode disposed over the oxygen reservoir layer.

In accordance with an embodiment of the present disclosure, a method of manufacturing a semiconductor device includes forming a first electrode material layer, forming an interfacial insulating material layer over the first electrode material layer, forming a first memory material layer over the interfacial insulating material layer, forming a second electrode material layer over the first memory material layer, forming a second memory material layer over the second electrode material layer, forming a third electrode material layer over the second memory material layer, and performing an oxygen scavenging process to extinguish the interfacial insulating material layer and to form a metal oxide layer between the second electrode material layer and the third electrode material layer.

In accordance with an embodiment of the present disclosure, a method of a semiconductor device includes forming a first electrode material layer including a polycrystalline silicon layer, forming an interfacial insulating material layer by oxidizing an upper surface of the first electrode material layer, forming a first memory material layer including a ferroelectric layer over the interfacial insulating material layer, forming a lower oxygen scavenging metal layer over the first memory material layer, forming a second memory material layer including a high-k dielectric layer over the lower oxygen scavenging metal layer, forming an upper oxygen scavenging metal layer over the second memory material layer, and performing an oxygen scavenging process to extinguish the interfacial insulation layer and to form an oxygen reservoir layer between the second memory material layer and the upper oxygen scavenging metal layer.

### BRIEF DESCRIPTION OF THE DRAWINGS

FIGS. 1A and 1B are circuit diagrams and perspective views schematically illustrating a cell array structure of a semiconductor device according to an embodiment of the present disclosure.

FIG. 2A is a circuit diagram schematically illustrating a cell array structure of a semiconductor device according to an embodiment of the present disclosure.

FIG. 2B is a longitudinal cross-sectional diagram schematically illustrating a unit cell of the semiconductor device.

FIG. 3 is a longitudinal cross-sectional view schematically illustrating a memory cell structure of a semiconductor device according to an embodiment of the present disclosure.

FIGS. 4A to 4E are schematic longitudinal cross-sectional views illustrating a method of forming a memory cell according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through one or more intervening elements. When two elements are identified as “directly connected” or “directly coupled,” one element is directly connected or directly coupled to the other element without any intervening element.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise to limit scope. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described hereunder. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the descriptions below. All changes within the meaning and range of equivalency of the claims are included within their scope.

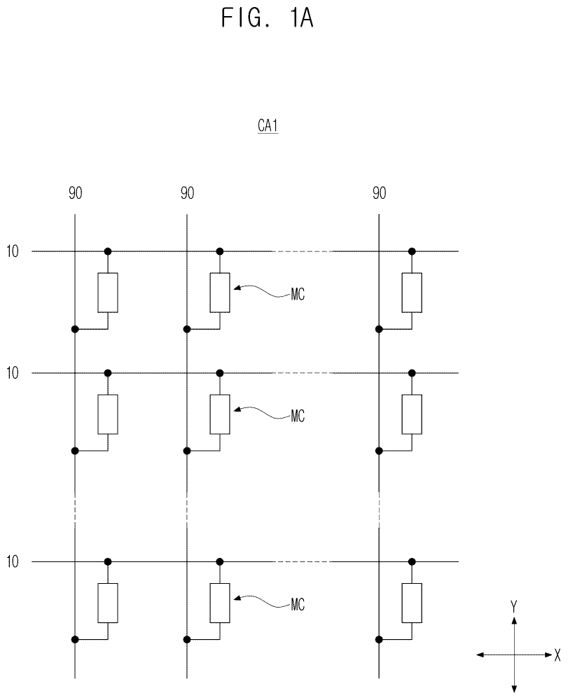

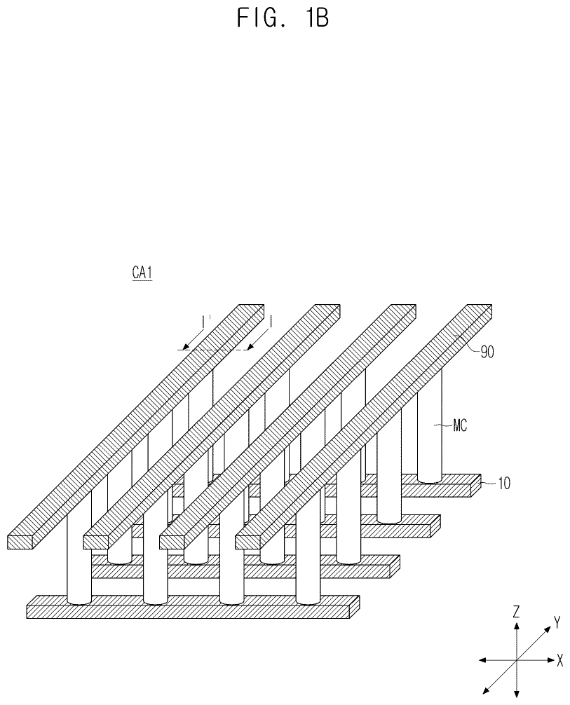

FIGS. 1A and 1B are circuit diagrams and perspective views schematically illustrating a cell array structure of a semiconductor device according to an embodiment of the present disclosure. Referring to FIGS. 1A and 1B, a cell array structure CA1 may include first interconnection lines 10, second interconnection lines 90, and memory cells MC. The first interconnection lines 10 may extend parallel to each other in a first horizontal direction X. For example, the first interconnection lines 10 may be word lines. The second interconnection lines 90 may extend parallel to each other in a second horizontal direction Y. For example, the second interconnection lines 90 may be bit lines. In another embodiment, the first interconnection lines 10 may be the bit lines, and the second interconnection lines 90 may be the word lines. The first horizontal direction X and the second horizontal direction Y may be perpendicular to each other. The memory cells MCs may be disposed at intersections between the first interconnection lines 10 and the second interconnection lines 90, respectively, from a plan view. Each of the memory cells MC may include a variable resistance element. Each of the memory cells MC may include two electrodes. For example, the memory cells MC may include first electrodes electrically connected to the first interconnection lines 10, and second electrodes electrically connected to the second interconnection lines 90, respectively.

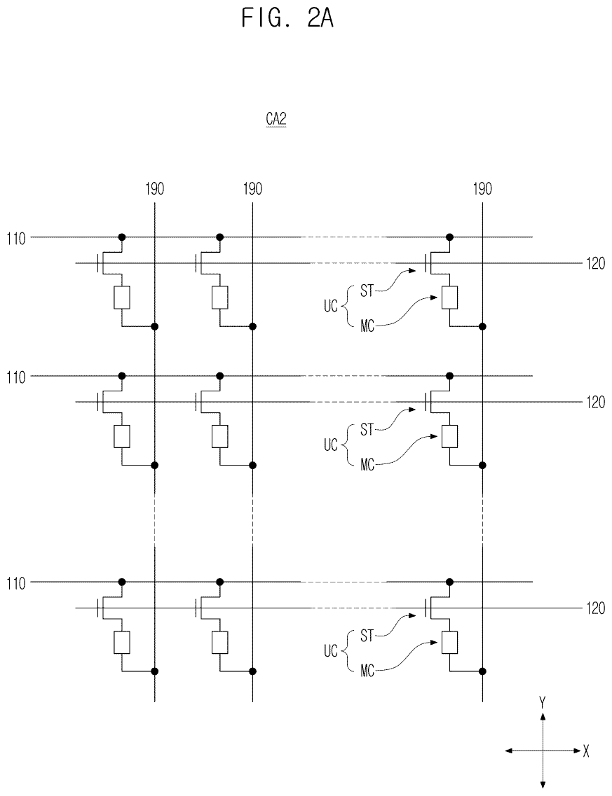

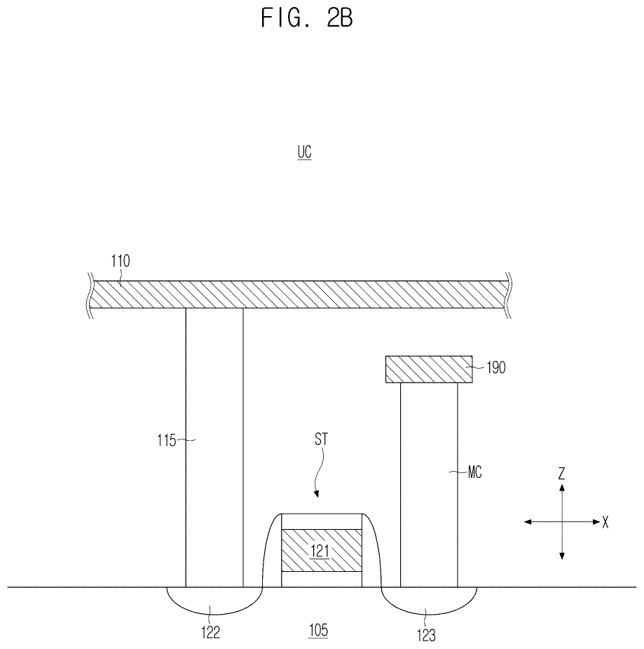

FIG. 2A is a circuit diagram schematically illustrating a cell array structure of a semiconductor device according to an embodiment of the present disclosure, and FIG. 2B is a longitudinal cross-sectional diagram schematically illustrating a unit cell of a semiconductor device. Referring to FIGS. 2A and 2B, a cell array structure CA2 may include active lines 110, word lines 120, source lines 190, and unit cells UC. The active lines 110 and the word lines 120 may extend parallel to each other in the first horizontal direction X. The source lines 190 may extend parallel to each other in the second horizontal direction Y. The unit cells UC may be disposed at intersections of the active lines 110 and the source lines 190, respectively. Each of the unit cells UC may include a selection transistor ST and a memory cell MC. The selection transistor ST may include a gate electrode 121 disposed on a substrate 105, a drain electrode 122 and a source electrode 123 formed in the substrate 105. The gate electrode 121 of the selection transistor ST may correspond to the word line 120. The drain electrode 122 of the selection transistor ST may be electrically connected to the active line 110 through an active contact plug 115. The source electrode 123 of the selection transistor ST may be electrically connected to the first electrode of the memory cell MC. The second electrode of the memory cell MC may be electrically connected to the source line 190. The substrate 105 may include a semiconducting layer such as a silicon layer. The active contact plug 115 may include a conductor such as a dopant doped polycrystalline silicon, a metal, a metal compound, a metal silicide, or a metal alloy. Reference numerals of the gate insulating layer, the gate capping layer, and the gate spacers of the selection transistor ST are omitted.

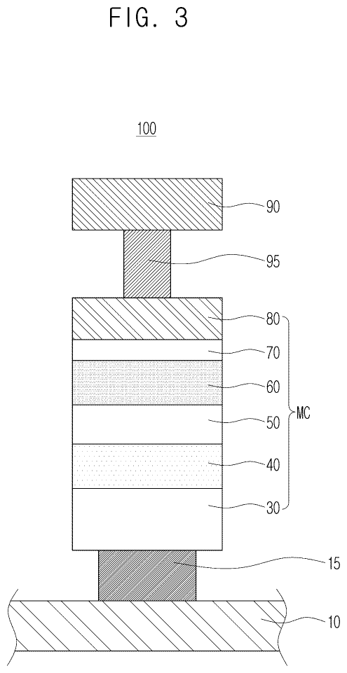

FIG. 3 is a longitudinal cross-sectional view taken along the line I-I′ of FIG. 1B schematically illustrating a memory cell structure of a semiconductor device according to an embodiment of the present disclosure. Referring to FIG. 3, a memory cell structure 100 may include a first interconnection line 10, a second interconnection line 90, and a memory cell MC between the first interconnection line 10 and the second interconnection line 90. The first interconnection line 10 and the second interconnection line 90 may have line shapes, respectively, that crossing each other from a plan view while extending in different horizontal directions. The memory cell MC may have a pillar shape extending in a vertical direction between the first interconnection line 10 and the second interconnection line 90. The memory cell structure 100 may further include a first contact plug 15 between the first interconnection line 10 and the memory cell MC and a second contact plug 95 between the memory cell MC and the second interconnection line 90.

The first interconnection line 10, the second interconnection line 90, the first contact plug 15, and the second contact plug 95 may include a conductor such as a metal, a metal alloy, a metal compound, a metal silicide, or dopant-doped silicon. In an embodiment, the first interconnection line 10, the second interconnection line 90, the first contact plug 15, and the second contact plug 95 may include multiple conductor layers. In an embodiment, referring to FIGS. 2A and 2B, the first interconnection line 10 may correspond to the source electrode 123 in the substrate 105, and the second interconnection line 90 may correspond to the source line 190.

The memory cell MC may include a lower electrode 30, a lower memory layer 40, a middle electrode 50, an upper memory layer 60, an oxygen reservoir layer 70, and an upper electrode 80.

The lower electrode 30 may include a polycrystalline silicon layer. For example, the lower electrode 30 may include an N-doped polycrystalline silicon layer doped with N-type ions such as phosphorous (P), arsenic (As), or antimony (Sb).

The lower memory layer 40 may include a ferroelectric layer. For example, the lower memory layer 40 may include at least one of a hafnium (Hf)-based compound layer, a zirconium (Zr)-based compound layer, or a hafnium-zirconium (HfZr)-based compound layer. The hafnium (Hf)-based compound layer may include a hafnium oxide (HfO)-based ferroelectric material layer, the zirconium (Zr)-based compound may include a zirconium oxide (ZrO)-based ferroelectric material layer, and the hafnium-Zr-based compound may include a hafnium zirconium oxide (HfZrO)-based ferroelectric material layer. In an embodiment, the lower memory layer 40 may include one of hafnium oxide (HfO₂), zirconium oxide (ZrO₂), or hafnium zirconium oxide (HfZrO). In another embodiment, the lower memory layer 40 may include at least one of impurity-doped hafnium oxide (HfO₂), impurity-doped zirconium oxide (ZrO₂), or impurity-doped hafnium zirconium oxide (HZO). The impurity may include at least one of carbon (C), silicon (Si), magnesium (Mg), aluminum (Al), yttrium (Y), nitrogen (N), germanium (Ge), arsenic (As), tin (Sn), gadolinium (Gd), lanthanum (La), scandium (Sc), and strontium (Sr).

The middle electrode 50 may include a metal layer. The middle electrode 50 may include an oxygen scavenging metal layer. For example, the middle electrode 50 may include a titanium (Ti) layer. In an embodiment, the middle electrode 50 may include a titanium oxide (TiO) layer. For example, a portion of the middle electrode 50 may be a titanium oxide layer (TiO). The middle electrode 50 may physically and materially separate the upper memory layer 60 from the lower memory layer 40.

The upper memory layer 60 may include a high-k dielectric layer. The upper memory layer 60 may include a metal oxide. For example, the upper memory layer 60 may include at least one of titanium oxide (TiO), vanadium oxide (VO), manganese oxide (MnO), iron oxide (FeO), cobalt oxide (CoO), zinc oxide (ZnO), yttrium oxide (YO), zirconium oxide (ZrO), niobium oxide (NbO), molybdenum oxide (MoO), ruthenium oxide (RuO), palladium oxide (PdO), barium oxide (BaO), lanthanum oxide (LaO), hafnium oxide (HfO), iridium oxide (IrO), or other transition metal oxides. In an embodiment, the upper memory layer 60 may be an amorphous material layer. For example, when the upper memory layer 60 is the amorphous material layer subject to an electric field, a conductive filament may be formed more easily than when the upper memory layer 60 is a crystalline material layer. In addition, the conductive filament can be more easily extinguished or electrically disconnected through physical deterioration.

The oxygen reservoir layer 70 may include at least one of a metal layer or a metal oxide layer. For example, the oxygen reservoir layer 70 may include at least one of a tantalum (Ta) layer, a hafnium (Hf) layer, a titanium (Ti) layer, a tantalum oxide (TaO) layer, a hafnium oxide (HfO) layer, or a titanium oxide (TiO) layer. The oxygen reservoir layer 70 may absorb and/or provide oxygen atoms from and/or into the upper memory layer 60. When the oxygen atoms are absorbed from the upper memory layer 60 into the oxygen reservoir layer 70, oxygen vacancies may be generated in the upper memory layer 60. Thus, conductive paths, such as for example conductive filaments, may be formed in the upper memory layer 60 through the movement of the oxygen vacancies. When the oxygen atoms are provided from the oxygen reservoir layer 70 into the upper memory layer 60, the oxygen vacancies may be dissipated. Thus, the conductive filaments may be dissipated. The middle electrode 50 may block and prevent the movement of the oxygen vacancies from the upper memory layer 60 to the lower memory layer 40.

The upper electrode 80 may include at least one of a metal layer, a metal compound layer, and a metal alloy layer. In an embodiment, the upper electrode 80 and the oxygen reservoir layer 70 may include the same metal. For example, the upper electrode 80 may include at least one of a tantalum (Ta) layer, a titanium (Ti) layer, a titanium nitride (TiN) layer, a titanium aluminum nitride (TiAlN) layer, or other conductive layers containing titanium (Ti) or tantalum (Ta).

The memory cell MC according to an embodiment of the present disclosure may include two memory storage elements, for example, lower and upper memory layers 40 and 60. The lower memory layer 40 may operate as a ferroelectric memory element. Therefore, the lower memory layer 40 can have lower off-current characteristics and stably operate at lower power compared to a non-ferroelectric material memory layer. That is, the memory cell MC can operate as a memory element layer that maintains faster and more stable data with lower power than a memory cell using a non-ferroelectric material memory layer. The upper memory layer 60 may operate as a variable resistance element layer using a high-k dielectric layer. For example, the memory element layer can operate as a variable resistive memory element layer whose conductivity changes by generating and dissipating conductive filaments depending on the applied voltage or current. Therefore, the memory cell MC can operate as a hybrid memory element having a ferroelectric memory element layer and a variable resistive memory element layer, and can have a high on/off current ratio.

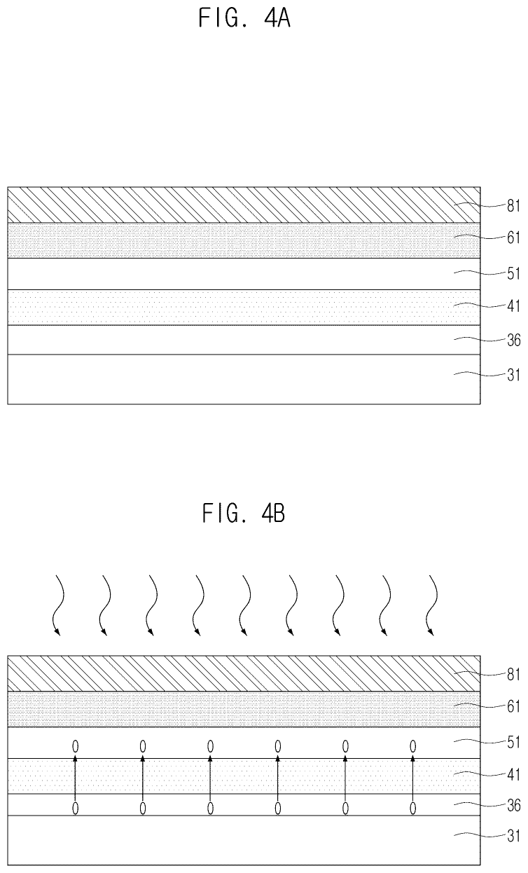

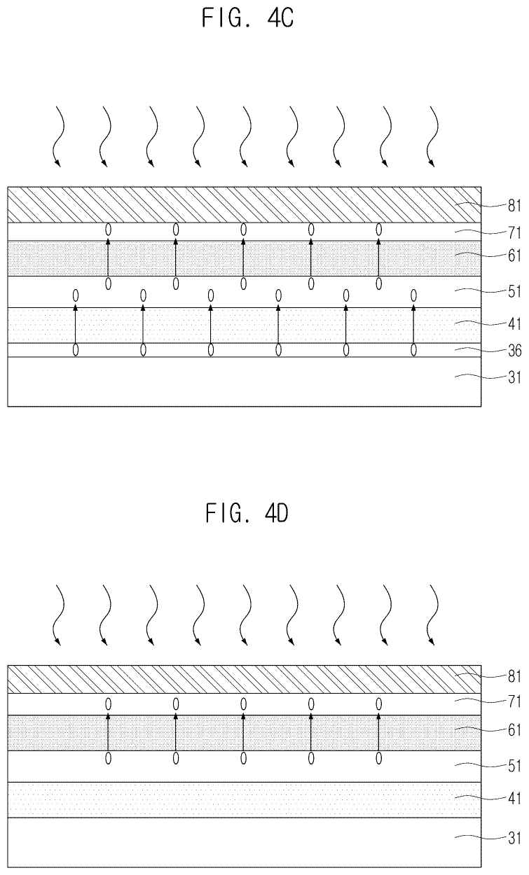

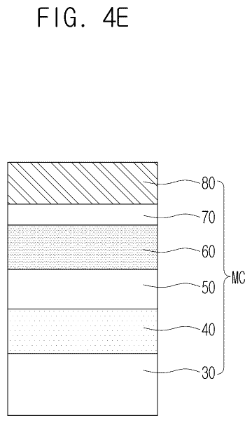

FIGS. 4A to 4E are schematic longitudinal cross-sectional views illustrating a method of forming a memory cell MC according to an embodiment of the present disclosure. Referring to FIG. 4A, a manufacturing method may include forming a lower electrode material layer 31, an interfacial material layer 36, a lower memory material layer 41, a middle electrode material layer 51, an upper memory material layer 61, and an upper electrode material layer 81.

The lower electrode material layer 31 may include a silicon layer. For example, forming the lower electrode material layer 31 may include forming a polycrystalline silicon layer using a deposition process. In an embodiment, the method may further include performing a process for providing dopants in the lower electrode material layer 31. For example, the method may further include performing an ion implantation process or an ion diffusion process. In an embodiment, during the deposition process for forming the lower electrode material layer 31, dopants may be provided at the same time.

The interfacial material layer 36 may include a silicon oxide (SiO₂) layer. For example, forming the interfacial material layer 36 may include forming a native oxide film on a surface of the lower electrode material layer 31 using a native oxidation reaction. In an embodiment, forming the interfacial material layer 36 may include oxidizing the surface of the lower electrode material layer 31. In another embodiment, forming the interfacial material layer 36 may include forming a silicon oxide (SiO₂) layer on the lower electrode material layer 31 by performing a deposition process. That is, the interfacial material layer 36 may include a silicon oxide layer or an oxidized silicon layer. The lower electrode material layer 31 and the interfacial material layer 36 may include a common material. For example, the lower electrode material layer 31 and the interfacial material layer 36 both may include silicon (Si).

The lower memory material layer 41 may include a ferroelectric material layer. In an embodiment, the lower memory material layer 41 may include HZO (HfZrO), and particularly, may include a crystalline or polycrystalline hafnium zirconium oxide layer. Forming the lower memory material layer 41 may include forming a hafnium zirconium oxide layer including hafnium (Hf), zirconium (Zr), and oxygen (O) on the interfacial material layer 36 using a deposition process. In an embodiment, the lower memory layer 40 may be a crystalline layer. For example, the lower memory layer 40 may include a crystalline hafnium zirconium oxide (HfZrO) layer.

The middle electrode material layer 51 may include a reactive metal layer such as titanium (Ti). For example, forming the middle electrode material layer 51 may include forming a metal layer containing titanium (Ti) on the lower memory material layer 41 by performing a deposition process. In an embodiment, the middle electrode material layer 51 may include a lower oxygen scavenging metal layer. In an embodiment, the lower oxygen scavenging metal layer may include a lower oxygen gettering layer. The lower oxygen scavenging metal layer or the lower oxygen gettering layer may include a titanium (Ti) layer.

The upper memory material layer 61 may include a high-k dielectric material layer. For example, the upper memory material layer 61 may include a hafnium oxide (HfO) layer. Forming the upper memory material layer 61 may include forming a hafnium oxide layer on the middle electrode material layer 51 by performing a deposition process. In an embodiment, the upper memory material layer 61 may include an amorphous hafnium oxide layer.

The upper electrode material layer 81 may include a reactive metal layer such as titanium (Ti). For example, forming the upper electrode material layer 81 may include forming a titanium (Ti) layer on the upper memory material layer 61 by performing a deposition process. In an embodiment, the upper memory material layer 61 may be an upper oxygen scavenging metal layer. In an embodiment, the upper oxygen scavenging metal layer may include an upper oxygen gettering layer. The upper oxygen scavenging metal layer or the upper oxygen gettering layer may include a titanium (Ti) layer.

Referring to FIG. 4B, the method may further include performing a first oxygen scavenging process to scavenge and move oxygen atoms from the interfacial material layer 36 to the middle electrode material layer 51. For example, the middle electrode material layer 51 may absorb the oxygen atoms from the interfacial material layer 36. Because the oxygen atoms are scavenged, the interfacial material layer 36 may be thinned. In an embodiment, the middle electrode material layer 51 may be generally lightly oxidized. In an embodiment, a portion of the middle electrode material layer 51 may be partially oxidized. For example, all or a part of the middle electrode material layer 51 may be modified with a titanium oxide layer. The middle electrode material layer 51 may slightly expand. In an embodiment, when the lower memory material layer 41 is a crystalline material layer, oxygen atoms may move from the interfacial material layer 36 to the middle electrode material layer 51 more smoothly than when the lower memory material layer 41 is an amorphous material layer. That is, the oxygen atoms may be scavenged more easily.

Referring to FIG. 4C, the method may further include performing a second oxygen scavenging process to continuously scavenge and move the oxygen atoms from the interfacial material layer 36 to the middle electrode material layer 51, and scavenge and move the oxygen atoms from the middle electrode material layer 51 to the upper electrode material layer 81. For example, the middle electrode material layer 51 may continuously absorb oxygen atoms from the interfacial material layer 36, and the upper electrode material layer 81 may absorb oxygen atoms from the middle electrode material layer 51 at the same time. Since the oxygen atoms are further scavenged, the interfacial material layer 36 may be further thinned. The oxygen atoms scavenged from the middle electrode material layer 51 may partially oxidize a lower portion of the upper electrode material layer 81. For example, a lower portion of the upper electrode material layer 81 may be partially oxidized to be modified into an oxygen reservoir material layer 71. In an embodiment, the oxygen reservoir material layer 71 may include at least one of a tantalum (Ta) layer, a hafnium (Hf) layer, a titanium (Ti) layer, a tantalum oxide (TaO) layer, hafnium oxide (HfO) layer, or a titanium oxide (TiO) layer. The middle electrode material layer 51 may absorb the oxygen atoms from the interfacial material layer 36 and provide the oxygen atoms to the upper electrode material layer 81.

Referring to FIG. 4D, the method may further include performing a third scavenging process to continuously scavenge and move the oxygen atoms from the interfacial material layer 36 to the middle electrode material layer 51 so that the interfacial material layer 36 is extinguished, and continuously scavenge and move the oxygen atoms from the middle electrode material layer 51 to the upper electrode material layer 81 so that the oxygen reservoir material layer 71 thickness increases. The interfacial material layer 36 may be extinguished. For example, all oxygen atoms in the interfacial material layer 36 are scavenged, so that the interfacial material layer 36 may be modified to the same material as the lower electrode material layer 31. The upper electrode material layer 81 may continuously absorb the oxygen atoms from the middle electrode material layer 51. Accordingly, the oxygen reservoir material layer 71 may be further thickened.

The first to third scavenging processes may be continuously performed without a vacuum break. For example, the first to third scavenging processes may be substantially one process. The first to third scavenging processes may include performing an annealing process. The annealing process may include heating at least one of the lower electrode material layer 31, the interfacial material layer 36, the lower memory material layer 41, the middle electrode material layer 51, the upper memory material layer 61, and the upper electrode material layer 81 in a range of about 300° C. to 600° C.

Referring to FIG. 4E, the method may further include forming a memory cell MC by patterning the lower electrode material layer 31, the lower memory material layer 41, the middle electrode material layer 51, the upper memory material layer 61, the oxygen reservoir material layer 71, and the upper electrode material layer 81 by performing a patterning process. Through patterning, the lower electrode material layer 31, the lower memory material layer 41, the middle electrode material layer 51, the upper memory material layer 61, the oxygen reservoir material layer 71, and the upper electrode material layer 81 may be formed into a lower electrode 30, a lower memory layer 40, a middle electrode 50, an upper memory layer 60, an oxygen reservoir layer 70, and an upper electrode 80. Thus, the memory cell MC may include the lower electrode 30, the lower memory layer 40, the middle electrode 50, the upper memory layer 60, the oxygen reservoir layer 70, and the upper electrode 80. In an embodiment, the method may further include forming a spacer layer conformally on both side surfaces and the top surface of the memory cell MC. The spacer layer may be an insulating material that does not include oxygen. For example, the spacer layer may include the insulating layer based on silicon nitride.

According to embodiments of the present disclosure, a semiconductor device having hybrid memory layers may operate at a low operating voltage and may have a high on/off current ratio.

While the present disclosure has been described with respect to some specific embodiments, it will be apparent to those skilled in the art that various changes and modifications may be made without departing from the spirit and scope of the disclosure as defined in the following claims.

What is claimed is:

1. A semiconductor device, comprising:
a first interconnection line extending in a first direction;
a second interconnection line extending in a second direction; and
a memory cell disposed between the first interconnection line and the second interconnection line,
wherein the memory cell includes:
a first electrode;
a first memory layer including a ferroelectric layer disposed over the first electrode;
a second electrode disposed over the first memory layer;
a second memory layer including a high-k dielectric layer disposed over the second electrode;
an oxygen reservoir layer disposed over the second memory layer; and
a third electrode disposed over the oxygen reservoir layer.

2. The semiconductor device of claim 1,
wherein the first electrode includes a polycrystalline silicon layer.

3. The semiconductor device of claim 1,
wherein the first memory layer includes a crystalline hafnium zirconium oxide layer.

4. The semiconductor device of claim 1,
Wherein the second electrode includes at least one of a titanium layer or a titanium nitride layer.

5. The semiconductor device of claim 1,
wherein the second memory layer includes an amorphous hafnium oxide layer.

6. The semiconductor device of claim 1,
wherein the second memory layer includes oxygen vacancies.

7. The semiconductor device of claim 1,
wherein the oxygen reservoir layer includes at least one of a tantalum layer, a hafnium layer, titanium layer, a tantalum oxide layer, a hafnium oxide layer, or a titanium oxide layer.

8. The semiconductor device of claim 1,
wherein the third electrode includes at least one of a titanium layer or a titanium nitride layer.

9. The semiconductor device of claim 1, further comprising:
a first contact plug between the first interconnection line and the memory cell.

10. The semiconductor device of claim 9, further comprising:
a second contact plug between the memory cell and the second interconnection line.

11. The semiconductor device of claim 1,
wherein the first direction and the second direction are perpendicular to each other.

12. A method of manufacturing a semiconductor device comprising:
forming a first electrode material layer,
forming an interfacial insulating material layer over the first electrode material layer,
forming a first memory material layer over the interfacial insulating material layer,
forming a second electrode material layer over the first memory material layer,
forming a second memory material layer over the second electrode material layer,
forming a third electrode material layer over the second memory material layer, and
performing an oxygen scavenging process to extinguish the interfacial insulating material layer and to form a metal oxide layer between the second electrode material layer and the third electrode material layer.

13. The method of claim 12,
wherein the first electrode material layer includes a polycrystalline silicon layer.

14. The method of claim 12,
wherein the interfacial insulating material layer includes silicon oxide.

15. The method of claim 14,
wherein forming the interfacial insulating material layer includes oxidizing an upper surface of the first electrode material layer.

16. The method of claim 12,
wherein the first memory material layer includes a ferroelectric layer and the ferroelectric layer includes a crystalline hafnium zirconium oxide layer.

17. The method of claim 12,
wherein the second electrode material layer includes at least one of titanium or titanium oxide.

18. The method of claim 12,
wherein the first memory material layer includes an amorphous hafnium oxide layer.

19. The method of claim 12,
wherein the metal oxide layer includes a titanium oxide layer.

20. The method of claim 12,
wherein the third electrode material layer includes at least one of a titanium layer or a titanium nitride layer.

21. The method of claim 12, further comprising:
patterning the first electrode material layer, the first memory material layer, the second electrode material layer, the second memory material layer, the metal oxide layer, and the third electrode material layer to form a memory cell including a first electrode, a first memory layer, a second electrode, a second memory layer, an oxygen reservoir layer, and a third electrode.

22. A method of manufacturing a semiconductor device comprising:
forming a first electrode material layer including a polycrystalline silicon layer,
forming an interfacial insulating layer by oxidizing an upper surface of the first electrode material layer,
forming a first memory material layer including a ferroelectric layer over the interfacial insulating layer,
forming a lower oxygen scavenging metal layer over the first memory material layer,
forming a second memory material layer including a high-k dielectric layer over the lower oxygen scavenging metal layer, forming an upper oxygen scavenging metal layer over the second memory material layer, and
performing an oxygen scavenging process to extinguish the interfacial insulation layer and to form an oxygen reservoir layer between the second memory material layer and the upper oxygen scavenging metal layer.

23. The method of claim 22,
wherein the ferroelectric layer includes a hafnium zirconium oxide layer.

24. The method of claim 22,
wherein the lower oxygen scavenging metal layer includes a titanium layer.

25. The method of claim 22,
wherein the high-k dielectric layer includes a hafnium oxide layer.

26. The method of claim 22,
wherein the upper oxygen scavenging metal layer includes a titanium layer.

27. The method of claim 22,
wherein the oxygen reservoir layer includes at least one of a tantalum layer, a hafnium layer, a titanium layer, a tantalum oxide layer, a hafnium oxide layer, or a titanium oxide layer.
